(19) United States
(12) Patent Application Publication
(10) Pub. No.: US 2024/0276832 A1
(43) Pub. Date: Aug. 15, 2024

(54) DISPLAY PANEL AND PREPARATION METHOD THEREOF AND DISPLAY DEVICE

(71) Applicant: Xiamen Tianma Display Technology Co., Ltd., Xiamen (CN)

(72) Inventors: Jiansheng ZHONG, Xiamen (CN); Jinjin YANG, Xiamen (CN); Shui HE, Xiamen (CN)

(73) Assignee: Xiamen Tianma Display Technology Co., Ltd., Xiamen (CN)

(21) Appl. No.: 18/643,343

(22) Filed: Apr. 23, 2024

(30) Foreign Application Priority Data
Dec. 15, 2023 (CN) 202311749256.8

(51) Int. Cl. H10K 59/65; H10K 59/12; H10K 59/121; H10K 59/80; H10K 71/60

(52) U.S. Cl. CPC H10K 59/65; H10K 59/1201; H10K 59/1213; H10K 59/873; H10K 71/60

(57) ABSTRACT

Provided are a display panel and a preparation method thereof and a display device. In the display panel, at least one groove is provided in an isolation region. A groove includes a first groove division and a second groove division which are communicated with each other, and the second groove division is located on a side of the first groove division facing away from a base substrate. Along a direction pointing from a display region to a notch region, a maximum length of the first groove division is greater than a maximum length of the second groove division. A cathode is disconnected at the groove.

### CROSS-REFERENCE TO RELATED APPLICATION(S)

This application claims priority to Chinese Patent Application No. 202311749256.8 filed Dec. 15, 2023, the disclosure of which is incorporated herein by reference in its entirety.

### TECHNICAL FIELD

The present disclosure relates to the field of display technology and, in particular, to a display panel and a preparation method thereof and a display device.

### BACKGROUND

To improve the screen-to-body ratio of the display panel, the display region of the display panel is punched to form a hole for accommodating the camera.

However, after the display panel is punched, the middle layer structure of the display panel is exposed at the cutting section of the hole. On the one hand, static electricity will enter the display region through the cutting section of the hole, causing abnormal display of the display region around the hole-punch region; on the other hand, at the cutting section of the hole, the middle layer structure of the display panel is charged, which can easily lead to electrochemically corroded dark spots, affecting the display quality.

### SUMMARY

The present disclosure provides a display panel and a preparation method thereof and a display device.

According to an aspect of the present disclosure, a display panel is provided. The display panel includes a hole-punch region, a display region surrounding the hole-punch region and an isolation region located between the display region and the hole-punch region.

The display panel further includes a base substrate, an array layer and a light-emitting functional layer, the array layer and the light-emitting functional layer are sequentially located on a side of the base substrate.

The array layer includes a first insulating layer.

The light-emitting functional layer includes a cathode, and the cathode extends from the display region to the isolation region.

A groove is provided in the isolation region, and the groove penetrates at least part of the first insulating layer.

The groove includes a first groove division and a second groove division which are communicated with each other, and the second groove division is located on a side of the first groove division facing away from the base substrate.

Along a direction pointing from the display region to the hole-punch region, a maximum length of the first groove division is greater than a maximum length of the second groove division, and the cathode is disconnected at the groove.

According to another aspect of the present disclosure, a preparation method of a display panel is provided. The display panel includes a hole-punch region, a display region surrounding the hole-punch region and an isolation region located between the display region and the hole-punch region.

The preparation method includes steps described below.

A first insulating layer is prepared on a side of a base substrate and an array layer is formed.

A groove is formed on the array layer of the isolation region, where the groove penetrates at least part of the first insulating layer, the groove includes a first groove division and a second groove division which are communicated with each other, the second groove division is located on a side of the first groove division facing away from the base substrate, and along a direction pointing from the display region to the hole-punch region, a maximum length of the first groove division is greater than a maximum length of the second groove division.

A light-emitting functional layer is prepared on the array layer, where the light-emitting functional layer includes a cathode, the cathode extends from the display region to the isolation region, and the cathode is disconnected at the groove.

According to another aspect of the present disclosure, a display device is provided. The display device includes the display panel described in the first aspect.

According to the display panel and the preparation method thereof and the display device provided in embodiments of the present disclosure, the groove is disposed in the isolation region between the display region and the hole-punch region, the groove includes the first groove division and the second groove division which is located on the side of the first groove division facing away from the base substrate, where the first groove division and the second groove division are communicated with each other, and along the direction pointing from the display region to the hole-punch region, the maximum length of the first groove division is greater than the maximum length of the second groove division.

It is to be understood that the content described in this section is neither intended to identify key or critical features of the embodiments of the present disclosure nor intended to limit the scope of the present disclosure. Other features of the present disclosure become easily understood through the description provided hereinafter.

### BRIEF DESCRIPTION OF DRAWINGS

To illustrate the technical solutions of embodiments of the present disclosure more clearly, the drawings used in the description of the embodiments are briefly described below. Apparently, the drawings described below merely illustrate part of the embodiments of the present disclosure, and those of ordinary skill in the art may obtain other drawings based on the drawings described below on the premise that no creative work is done.

FIG. 1 is a structural diagram of a display panel according to an embodiment of the present disclosure;

FIG. 2 is a sectional diagram taken along direction A-A′ of FIG. 1;

FIG. 3 is a sectional diagram of a display panel according to an embodiment of the present disclosure;

FIG. 4 is a sectional diagram of another display panel according to an embodiment of the present disclosure;

FIG. 5 is a structural diagram of a metal isolation column according to an embodiment of the present disclosure;

FIG. 6 is a sectional diagram of another display panel according to an embodiment of the present disclosure;

FIG. 7 is a sectional diagram of another display panel according to an embodiment of the present disclosure;

FIG. 8 is a flowchart of a preparation method of a display panel according to an embodiment of the present disclosure;

FIG. 9 and FIG. 10 are structural diagrams of a flow of a preparation method of a display panel according to an embodiment of the present disclosure;

FIG. 11 to FIG. 16 are structural diagrams of a flow of another preparation method of a display panel according to an embodiment of the present disclosure;

FIG. 17 to FIG. 19 are structural diagrams of a flow of another preparation method of a display panel according to an embodiment of the present disclosure; and

FIG. 20 is a structural diagram of a display device according to an embodiment of the present disclosure.

### DETAILED DESCRIPTION

To make the solutions of the present disclosure better understood by those skilled in the art, the technical solutions of the embodiments of the present disclosure are described below clearly and completely in conjunction with the drawings in the embodiments of the present disclosure. Apparently, the embodiments described below are part, not all, of the embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims and drawings of the present disclosure are used for distinguishing between similar objects and are not necessarily used for describing a particular order or sequence. It is to be understood that the data used in this manner is interchangeable in appropriate cases so that the embodiments of the present disclosure described herein can be implemented in an order not illustrated or described herein. Additionally, the terms “including”, “having” and variations thereof are intended to encompass a non-exclusive inclusion. For example, a process, method, system, product or device that includes a series of steps or units not only includes the expressly listed steps or units but may also include other steps or units that are not expressly listed or are inherent to such a process, method, product or device.

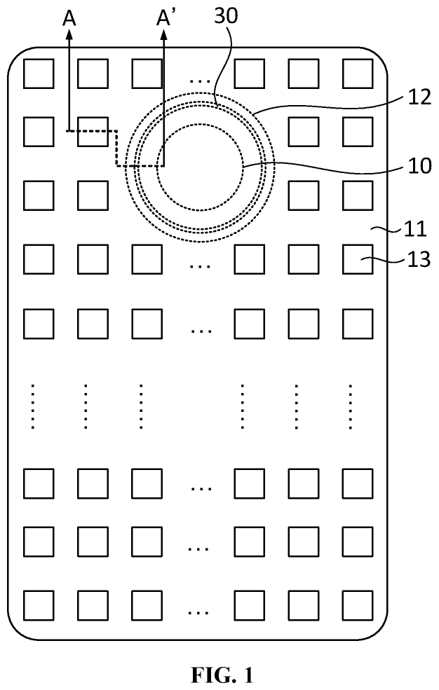

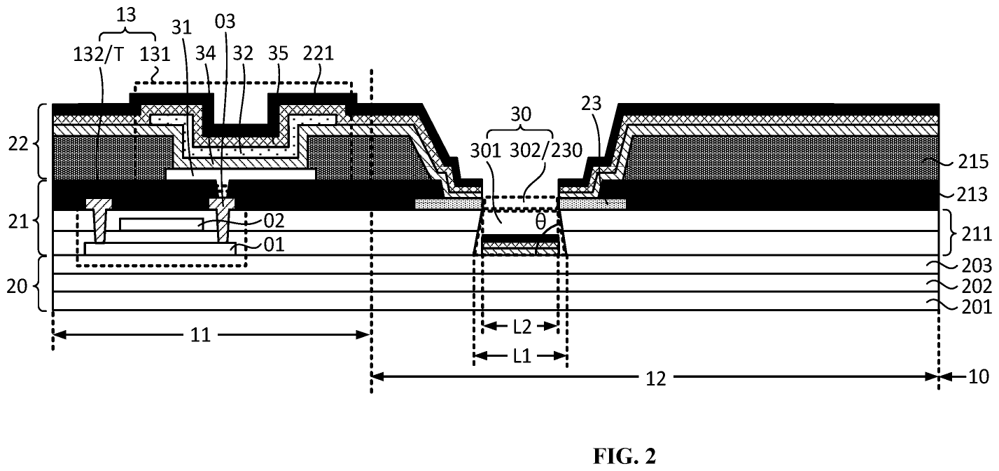

FIG. 1 is a structural diagram of a display panel according to an embodiment of the present disclosure, and FIG. 2 is a sectional diagram taken along direction A-A′ of FIG. 1. As shown in FIG. 1 and FIG. 2, a display panel provided in the embodiment of the present disclosure includes a hole-punch region 10, a display region 11 surrounding the hole-punch region 10 and an isolation region 12 located between the display region 11 and the hole-punch region 10. The display panel further includes a base substrate 20, an array layer 21 and a light-emitting functional layer 22. The array layer 21 and the light-emitting functional layer 22 are sequentially located on a side of the base substrate 20. The array layer 21 includes a first insulating layer 211. The light-emitting functional layer 22 includes a cathode 221, and the cathode 221 extends from the display region 11 to the isolation region 12. At least one groove 30 is provided in the isolation region 12, and the at least one groove 30 penetrates at least part of the first insulating layer 211. A groove 30 of the at least one groove 30 includes a first groove division 301 and a second groove division 302 which are communicated with each other, and the second groove division 301 is located on a side of the first groove division 301 facing away from the base substrate 20. Along a direction pointing from the display region 11 to the hole-punch region 10, a maximum length L1 of the first groove division 301 is greater than a maximum length L2 of the second groove division 302, and the cathode 221 is disconnected at the groove 30.

Illustratively, as shown in FIG. 1 and FIG. 2, the hole-punch region 10 is configured for placing a photosensitive element. The photosensitive element may be, but is not limited to, a camera, a light sensor, a distance sensor, a depth sensor, an iris recognition sensor or an infrared sensor.

The hole-punch region 10 may be a non-display region. That is, the hole-punch region 10 does not emit light so that the impact on the use performance of the photosensitive element is reduced.

In addition, the hole-punch region 10 may be a rectangular region, a circular region or an elliptical region. The position of the hole-punch region 10 may be disposed on any side of the display panel. Those skilled in the art may configure the shape and the position of the hole-punch region 10 according to actual requirements, which is not limited in the embodiment of the present disclosure.

With continued reference to FIG. 1 and FIG. 2, the display region 11 is disposed around the hole-punch region 10. The display region 11 includes multiple subpixels 13 arranged in an array. A subpixel 13 of the multiple subpixels 13 may include a light-emitting unit 131 and a pixel driver circuit 132 electrically connected to the light-emitting unit 131. The pixel driver circuit 132 is configured to drive the light-emitting unit 131 electrically connected to the pixel driver circuit 132 to emit light so that the display function is achieved.

Further, as shown in FIG. 2, the display panel further includes the base substrate 20. The base substrate 20 may further includes a first base 201, a first inorganic layer 202 and a second base 203 which are sequentially disposed.

Materials of the first base 201 and the second base 203 may include, but are not limited to, organic materials such as polyimide.

The first inorganic layer 202 can block moisture and oxygen from entering the pixel driver circuit 132, thereby ensuring the driving performance of the pixel driver circuit 132. A material of the first inorganic layer 202 may include, but is not limited to, SiOx or SiNx.

With continued reference to FIG. 2, the array layer 21 is disposed on the side of the base substrate 20, and the pixel driver circuit 132 is disposed in the array layer 21. The pixel driver circuit 132 includes at least one thin-film transistor T, and the thin-film transistor T may include an active layer 01, a gate layer 02 and a source-drain electrode layer 03 which are laminated. The array layer 21 further includes the first insulating layer 211, and the first insulating layer 211 may include multiple insulating film layers. The first insulating layer 211 is configured to isolate the active layer 01, the gate layer 02 and the source-drain electrode layer 03 to ensure the normal operation of the thin-film transistor T.

A material of the first insulating layer 211 may include, but is not limited to, SiOx or SiNx.

With continued reference to FIG. 2, the light-emitting functional layer 22 is disposed on a side of the array layer 21 facing away from the base substrate 20. The light-emitting unit 131 is disposed in the light-emitting functional layer 22. An example where the display panel is an organic light-emitting diode (OLED) display panel is illustrated. The light-emitting unit 131 may be an organic light-emitting diode. The light-emitting unit 131 may include an anode 31, a light-emitting layer 32 and a cathode 221 which are laminated. The light-emitting layer 32 may be an organic light-emitting layer (EML). Electrons are injected into the light-emitting layer 32 through the cathode 221, holes are injected into the light-emitting layer 32 through the anode 31, and electrons and holes are combined in the light-emitting layer 32 to emit light.

It is to be noted that the pixel driver circuit 132 is configured to transmit a drive current to the light-emitting unit 131 under the action of signals of drive signal lines (such as a scan signal line, a data signal line and a power supply signal line) on the display panel to provide the drive current for the light-emitting unit 131. Moreover, electrons and holes are injected into the light-emitting layer 32 through the cathode 221 and the anode 31 respectively, forming excitons in the light-emitting layer 32 and exciting light-emitting molecules. Thus, the light-emitting layer 32 emits visible light.

With continued reference to FIG. 2, optionally, a first functional layer 34 may further be disposed between the anode 31 and the light-emitting layer 32, and the first functional layer 34 may include a hole injection layer (HIL) and a hole transport layer (HTL). The hole injection layer (HIL) mainly enhances the capability of transferring holes from the anode 31 to the light-emitting layer 32, while the hole transport layer (HTL) mainly plays a role in transferring holes to the light-emitting layer 32.

A second functional layer 35 may further be disposed between the light-emitting layer 32 and the cathode 221. The second functional layer 35 may include an electron transport layer (ETL) and an electron injection layer (EIL). The electron transport layer (ETL) mainly plays a role in transferring electrons to the light-emitting layer 32, while the electron injection layer (EIL) mainly enhances the capability of transferring electrons from the cathode 221 to the light-emitting layer 32, which is conducive to reducing a drive voltage of the light-emitting unit 131.

The inventor found through the research that the cathode 221 is generally set as a whole layer, and the cathode 221 extends from the display region 11 to the cutting section of the hole-punch region 10. Therefore, the cutting section of the hole-punch region 10 will expose the cross-section of the cathode 221. On the one hand, in the copper rod friction test or the electrostatic discharge (ESD) test, the generated static electricity will enter the display region 11 through the cutting section of the hole-punch region 10 from the cathode 221, causing electrical interference to the subpixels 13 of the display region 11, ultimately leading to abnormal display in the display region 11 around the hole-punch region 10; on the other hand, in the reliability (RA) test under high temperature and high humidity conditions, water vapor and oxygen in the environment are easy to seep into the cutting section of the hole-punch region 10, and the cathode 221 is charged at the cutting section of the hole-punch region 10, which can easily lead to electrochemically corroded dark spots and affect the display quality.

On the basis of the preceding technical problems, as shown in FIG. 1 and FIG. 2, in the embodiment of the present disclosure, the isolation region 12 is disposed between the display region 11 and the hole-punch region 10. At least one groove 30 is disposed in the isolation region 12, and the at least one groove 30 penetrates at least part of the first insulating layer 211. The cathode 221 is located on the side of the first insulating layer 211 facing away from the base substrate 20. Therefore, when the cathode 221 is prepared, part of the cathode 221 will fall in the groove 30.

Further, the groove 30 includes the first groove division 301 and the second groove division 302 which is located on the side of the first groove division 301 facing away from the base substrate 20, and the first groove division 301 and the second groove division 302 are communicated. Along the direction pointing from the display region 11 to the hole-punch region 10, the maximum length L1 of the first groove division 301 is greater than the maximum length L2 of the second groove division 302, so that the size of the first groove division 301 at the lower part of the groove 30 is greater than the size of the second groove division 302 at the upper part of the groove 30. Therefore, when the cathode 221 is prepared, a side wall of the groove 30 will not be easily covered by the cathode 221, and thus the cathode 221 is disconnected at the side wall of the groove 30. In this manner, when static electricity is introduced through the cathode 221 at the cutting section of the hole-punch region 10, the transmission path will be cut off at the side wall of the groove 30 in the isolation region 12, so the static electricity cannot enter the display region 11, electrical interference on the subpixels 13 of the display region 11 caused by the static electricity can be avoided, and thus the problem of abnormal display of the display region 11 around the hole-punch region 10 is solved. Moreover, a power signal transmitted on the cathode 221 cannot be transmitted through the isolation region 12 to the cutting section of the hole-punch region 10, so that the problem of electrochemically corroded dark spots formed at the cutting section of the hole-punch region 10 is solved, and the display quality is improved.

It is to be noted that as shown in FIG. 2, the first functional layer 34 and the second functional layer 35 are generally disposed as whole layers. As a result, the first functional layer 34 and the second functional layer 35 will also extend from the display region 11 to the cutting section of the hole-punch region 10, and the cutting section of the hole-punch region 100 will expose cross-sections of the first functional layer 34 and the second functional layer 35. Water vapor and oxygen in the environment can seep into the display region 11 through the cutting section of the hole-punch region 10 from the first functional layer 34 and the second functional layer 35, and the water vapor entering the display region 11 will lead to corrosion of surrounding lines, affecting the display quality.

On the basis of the preceding technical problems, as shown in FIG. 2, the groove 30 penetrates at least part of the first insulating layer 211, and the first functional layer 34 and the second functional layer 35 are located on the side of the first insulating layer 211 facing away from the base substrate 20. Therefore, when the first functional layer 34 and the second functional layer 35 are prepared, part of the first functional layer 34 and the second functional layer 35 will also fall in the groove 30.

Further, the size of the first groove division 301 at the lower part of the groove 30 is greater than the size of the second groove division 302 at the upper part of the groove 30. Therefore, when the first functional layer 34 and the second functional layer 35 are prepared, the side wall of the groove 30 will not be easily covered by the first functional layer 34 and the second functional layer 35, and thus the first functional layer 34 and the second functional layer 35 are disconnected at the side wall of the groove 30. In this manner, when water vapor and oxygen seep through the first functional layer 34 and the second functional layer 35 at the cutting section of the hole-punch region 10, the transmission path will be separated at the side wall of the groove 30 in the isolation region 12 so that the water vapor and oxygen cannot enter the display region 11, impact on the display quality of the display region 11 caused by the water vapor and oxygen can be reduced, and thus the display effect is improved.

In summary, according to the display panel provided in the embodiment of the present disclosure, the groove is disposed in the isolation region between the display region and the hole-punch region, the groove includes the first groove division and the second groove division which is located on the side of the first groove division facing away from the base substrate, where the first groove division and the second groove division are communicated with each other, and along the direction pointing from the display region to the hole-punch region, the maximum length of the first groove division is greater than the maximum length of the second groove division. In this manner, when the cathode is prepared, the side wall of the groove is not easily covered by the cathode, so that the cathode is disconnected at the side wall of the groove. Therefore, when static electricity is introduced through the cathode at the cutting section of the hole-punch region, the transmission path will be cut off at the side wall of the groove in the isolation region, so that the static electricity cannot enter the display region, electrical interference on the subpixels of the display region caused by the static electricity can be avoided, and thus the problem of abnormal display of the display region around the hole-punch region is solved. Moreover, a power signal transmitted on the cathode cannot be transmitted through the isolation region to the cutting section of the hole-punch region, so that the problem of electrochemically corroded dark spots formed at the cutting section of the hole-punch region is solved, and the display quality is improved.

With continued referent to FIG. 2, optionally, an angle between a bottom surface of the first groove division 301 and a side wall of the first groove division 301 is θ, where 0<θ<90°.

Specifically, as shown in FIG. 1 and FIG. 2, the groove 30 is disposed around the hole-punch region 10 to comprehensively separate the cathode 221. In the embodiment, the included angle θ between the bottom surface of the first groove division 301 and the side wall of the first groove division 301 is set as an acute angle so that the steepness of the slope of the side wall of the first groove division 301 may be increased. Therefore, when the cathode 221 is prepared on the side of the first insulating layer 211 facing away from the base substrate 20, the cathode 221 is disconnected at the position of the side wall of the first groove division 301. In this manner, when static electricity is introduced through the cathode 221 at the cutting section of the hole-punch region 10, the transmission path will be cut off at the side wall of the first groove division 301, so the static electricity cannot enter the display region 11, interference on the display region 11 caused by the static electricity can be avoided, and thus the problem of abnormal display of the display region 11 around the hole-punch region 10 is solved. Moreover, a power signal transmitted on the cathode 221 cannot be transmitted through the groove 30 to the cutting section of the hole-punch region 10 so that the problem of electrochemically corroded dark spots formed at the cutting section of the hole-punch region 10 is solved, and the display quality is improved.

With continued reference to FIG. 2, in the embodiment, along the direction pointing from the display region 11 to the hole-punch region 10, a section of the first groove division 301 is a trapezoid. In this case, the side wall of the first groove division 301 is, but not limited to, a plane.

In other embodiments, along the direction pointing from the display region 11 to the hole-punch region 10, the section of the first groove division may also be a circle or an ellipse. In this case, the side wall of the first groove division 301 is a curved surface, which is not specifically limited in the embodiment of the present disclosure.

It is to be noted that the specific size of the groove 30 may be set according to actual requirements. For example, along the direction pointing from the display region 11 to the hole-punch region 10, the maximum length L1 of the first groove division 301 satisfies that 50 μm≤L1≤100 μm, and the maximum length L2 of the second groove division 302 satisfies that 30 μm≤L2≤80 μm; therefore, it can be ensured that the maximum length L1 of the first groove division 301 is greater than the maximum length L2 of the second groove division 302, so that the cathode 221 can be disconnected at the side wall of the groove 30 while the difficulty of the process is reduced, and thus the process is easy to achieve. The specific size of the groove 30 is not limited thereto and is not limited in the embodiment of the present disclosure.

With continued reference to FIG. 2, the display panel provided in the embodiment of the present disclosure further includes a barrier layer 23, and the barrier layer 23 is located on the side of the first insulating layer 211 facing away from the base substrate 20. The second groove division 302 penetrates the barrier layer 23, and a vertical projection of the second groove division 302 on the base substrate 20 is located within a vertical projection of the first groove division 301 on the base substrate 20.

Illustratively, as shown in FIG. 2, the barrier layer 23 is disposed on the side of the first insulating layer 211 facing away from the base substrate 20, the first groove division 301 is located in the first insulating layer 211 located on a side of the barrier layer 23 close to the base substrate 20, the barrier layer 23 is provided with a hollowed-out region 230, and the hollowed-out region 230 is located within the groove 30, forming the second groove division 302 of the groove 30.

When the groove 30 is prepared, the first insulating layer 211 is etched through the hollowed-out region 230 of the barrier layer 23. The barrier layer 23 can play a role in blocking the etching and the etching of the first insulating layer 211 is implemented simultaneously along the vertical direction and the horizontal direction, forming the first groove division 301. Thus, the width of the first groove division 301 can be externally expanded. Finally, along the direction pointing from the display region 11 to the hole-punch region 10, the maximum length L1 of the first groove division 301 is greater than the maximum length L2 of the second groove division 302. In this manner, the steepness of the slope of the side wall of the groove 30 is increased. When the cathode 221 is formed on the side the first insulating layer 211 facing away from the base substrate 20, it is ensured that the cathode 221 is disconnected at the position of the side wall of the groove 30. Therefore, when static electricity is introduced through the cathode 221 at the cutting section of the hole-punch region 10, the transmission path will be cut off at the side wall of the groove 301 so that the static electricity cannot enter the display region 11, and thus interference on the display region 11 caused by the static electricity can be avoided. Moreover, a power signal transmitted on the cathode 221 cannot be transmitted through the groove 30 to the cutting section of the hole-punch region 10, so the problem of electrochemically corroded dark spots formed at the cutting section of the hole-punch region 10 is solved, and the display quality is improved.

It is to be noted that the preceding vertical direction is parallel to a thickness direction of the base substrate 20, and the horizontal direction is perpendicular to the thickness direction of the base substrate 20.

Optionally, a material of the barrier layer 23 includes a metal oxide or metal.

Specifically, when the groove 30 is prepared, the first insulating layer 211 may be etched by using a dry etching process.

Dry etching is a technique that uses plasma for thin film etching.

In the embodiment, when the first insulating layer 211 is etched by using the dry etching process, a suitable gas may be selected according to the material of the first insulating layer 211 for fast reaction with the material of the first insulating layer 211 so that the purpose of etching removal can be achieved. Dry etching has the advantages of controllability, flexibility, good repeatability, safe operation, easy automation, no chemical waste liquid, no pollution introduced in the treatment process and high cleanliness.

Fluorine-based plasma (such as etching gas SF6 or CF4) may be used for etching the first insulating layer 211, ensuring that the etching effect is achieved on the inorganic layer (that is, the first insulating layer 211), and no etching effect is achieved on the metal film layer, thereby avoiding damage to other metal structures.

In the embodiment, the material of the barrier layer 23 may be a metal oxide or metal. Therefore, when the groove 30 is prepared, the barrier layer 23 will not be etched, and the barrier layer 23 plays a role in blocking etching. Moreover, the hollowed-out region 230 in the barrier layer 23 forms the second groove division 302 of the groove 30. Plasma etches the first insulating layer 211 along both the vertical direction and the horizontal direction so that the first groove division 301 is formed, and thus the width of the first groove division 301 can be expanded externally. Finally, along the direction pointing from the display region 11 to the hole-punch region 10, the maximum length L1 of the first groove division 301 is greater than the maximum length L2 of the second groove division 302, and it is ensured that the cathode 221 is disconnected at the position of the side wall of the groove 30. Therefore, when static electricity is introduced through the cathode 221 at the cutting section of the hole-punch region 10, the transmission path will be cut off at the side wall of the groove 301 so that interference on the display region 11 caused by the static electricity can be avoided. Moreover, a power signal transmitted on the cathode 221 cannot be transmitted through the groove 30 to the cutting section of the hole-punch region 10, so the problem of electrochemically corroded dark spots formed at the cutting section of the hole-punch region 10 is solved, and the display quality is improved.

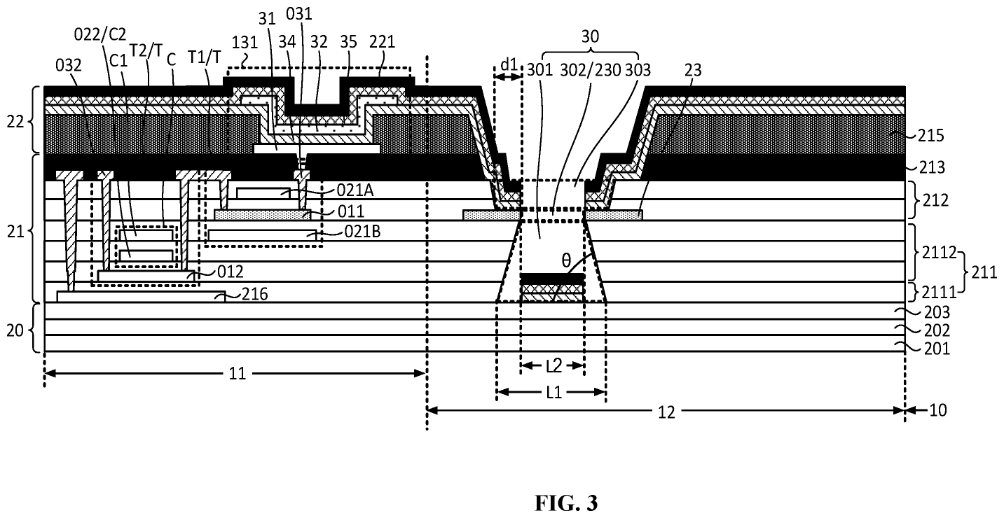

FIG. 3 is a sectional diagram of a display panel according to an embodiment of the present disclosure. As shown in FIG. 3, the array layer 21 further includes a first transistor T1, where the first transistor T1 includes a first active layer 011, and a material of the first active layer 011 is a metal oxide. The material of the barrier layer 23 is a metal oxide, and the barrier layer 23 and the first active layer 011 are located in the same film layer.

As shown in FIG. 3, the thin-film transistor T in the pixel driver circuit may include the first transistor T1. The first transistor T1 is an oxide semiconductor transistor, such as an N-type indium gallium zinc oxide (IGZO) transistor. Therefore, the first transistor T1 has the advantages of low mobility and a small leakage current, which is conducive to solving the current leakage problem during low-frequency driving and improving the stability of low-frequency driving of the pixel driver circuit.

In the embodiment, the barrier layer 23 is disposed in the same layer as the first active layer 011 of the first transistor T1 so that the setting of one film layer can be reduced, and thereby the purpose of reducing production costs and reducing the thickness of the display panel can be achieved.

Moreover, the material of the first active layer 011 of the first transistor T1 is a metal oxide, and the barrier layer 23 may use the same material as the first active layer 011. Therefore, while the barrier layer 23 can play a role in blocking etching, the barrier layer 23 can be prepared in the same process as the first active layer 011 so that the process time can be shortened.

It is to be noted that the barrier layer 23 located in the same film layer as the first active layer 011 refers to that the barrier layer 23 and the first active layer 011 are formed through the same mask process so that the number of masks can be reduced and manufacturing costs can be lowered.

With continued reference to FIG. 3, optionally, the first transistor T1 further includes a first gate layer 021A, a second gate layer 021B and a first source-drain electrode layer 031 which is connected to the first active layer 011. In this case, the first transistor T1 is a dual-gate transistor.

The dual-gate transistor has the characteristic of a low leakage current. The first transistor T1 uses a dual-gate transistor so that the current leakage problem during low-frequency driving can be effectively solved. Therefore, the pixel driver circuit is suitable for low-frequency driving, which is conducive to reducing the power consumption of the display panel.

Moreover, due to the typically large size of the oxide semiconductor transistor, setting the oxide semiconductor transistor as a dual-gate transistor is conducive to reducing the size of the first transistor T1 and further improving the pixel density.

With continued reference to FIG. 3, the array layer 21 further includes a second insulating layer 212, and along the thickness direction of the base substrate 20, the second insulating layer 212 is located between the barrier layer 23 and the light-emitting functional layer 22. The groove 30 further includes a third groove division 303 communicated with the second groove division 302, and the third groove division 303 is located on a side of the second groove division 302 facing away from the base substrate 20. The third groove division 303 penetrates the second insulating layer 212, and a vertical projection of the third groove division 303 on the base substrate 20 covers the vertical projection of the second groove division 302 on the base substrate 20.

Illustratively, as shown in FIG. 3, the second insulating layer 212 is further disposed between the barrier layer 23 and the light-emitting functional layer 22. The second insulating layer 212 may include one or more insulating film layers. On the one hand, the second insulating layer 212 may be used for isolating metal layers located in different film layers to ensure the normal operation of the pixel driver circuit; on the other hand, the second insulating layer 212 may also play a role of planarization, thus improving the quality of film layers above the second insulating layer 212.

A material of the second insulating layer 212 may include, but is not limited to, SiOx or SiNx to provide the insulation effect.

Further, while preparing the groove 30, the second insulating layer 212 can be etched first and the third groove division 303 is formed on the second insulating layer 212. The third groove division 303 exposes the hollowed-out region 230 in the barrier layer 23, and thus the first insulating layer 211 is further etched through the hollowed-out region 230 so that the first groove division 301 is formed in the first insulating layer 211.

The vertical projection of the third groove division 303 on the base substrate 20 covers the vertical projection of the second groove division 302 on the base substrate 20, so the third groove division 303 on the second insulating layer 212 can fully expose the hollowed-out region 230 in the barrier layer 23, thereby facilitating subsequent etching of the first insulating layer 211 through the hollowed-out region 230 to form the first groove division 301.

Optionally, when the third groove division 303 is prepared, the second insulating layer 212 may be etched by using a dry etching process. Dry etching is a technique that uses plasma for thin film etching.

In the embodiment, when the second insulating layer 212 is etched by using the dry etching process, a suitable gas may be selected according to the material of the second insulating layer 212 for fast reaction with the material of the second insulating layer 212 so that the purpose of etching removal can be achieved. Dry etching has the advantages of controllability, flexibility, good repeatability, safe operation, easy automation, no chemical waste liquid, no pollution introduced in the treatment process and high cleanliness.

Fluorine-based plasma (such as etching gas SF6 or CF4) may be used for etching the second insulating layer 212, ensuring that the etching effect is only achieved on the inorganic layer (that is, the second insulating layer 212), and no etching effect is achieved on the metal film layer, thereby avoiding damage to other metal structures.

With continued reference to FIG. 3, optionally, a vertical projection ofa side wall of the third groove division 303 on the base substrate 20 is located within a vertical projection of the barrier layer 23 on the base substrate 20.

As shown in FIG. 3, along the thickness direction of the base substrate 20, the vertical projection of the side wall of the third groove division 303 overlaps the vertical projection of the barrier layer 23. In this manner, on the one hand, it can be ensured that the third groove division 303 can fully expose the hollowed-out region 230 in the barrier layer 23, thereby facilitating the subsequent etching of the first insulating layer 211 through the hollowed-out region 230 to form the first groove division 301; on the other hand, when the first insulating layer 211 is etched through the third groove division 303 and the hollowed-out region 230, the barrier layer 23 can completely block the etching, avoiding the etching of part of the first insulating layer 211 outside the hollowed-out region 230 that is not covered by the barrier layer 23.

With continued reference to FIG. 3, optionally, along the direction pointing from the display region 11 to the hole-punch region 10, a shortest distance between the side wall of the third groove division 303 and a side wall of the second groove division 302 is d1, where d1≥10 μm.

As shown in FIG. 3, along the direction pointing from the display region 11 to the hole-punch region 10, it is set that the shortest distance d1 between the side wall of the third groove division 303 and the side wall of the second groove division 302 is greater than or equal to 10 μm, so along the direction pointing from the display region 11 to the hole-punch region 10, the size of the third groove division 303 is at least 20 μm greater than the size of the second groove division 302. In this manner, when the second insulating layer 212 is etched to form the third groove division 303, process errors that may cause the third groove division 303 not fully exposing the hollowed-out region 230 (that is, the second groove division 302) in the barrier layer 23 can be avoided. Moreover, the size of the third groove division 303 is greater than the size of the second groove division 302, which can also facilitate subsequent etching of the first insulating layer 211 through the second groove division 302 to form the first groove division 301.

It is to be noted that the display panel may further include other film layer structures. For example, as shown in FIG. 2 and FIG. 3, the array layer 21 further includes a planarization layer 213 and a pixel defining layer 215. The planarization layer 213 is located on a side of the thin-film transistor T facing away from the base substrate 20, and the pixel defining layer 215 is located on a side of the planarization layer 213 facing away from the base substrate 20. The pixel defining layer 215 includes a pixel opening, and the light-emitting layer 32 is connected to the anode 31 through the pixel opening. Film layer structures in the display panel are not limited thereto. Those skilled in the art may set other film layer structures in the display panel according to actual requirements.

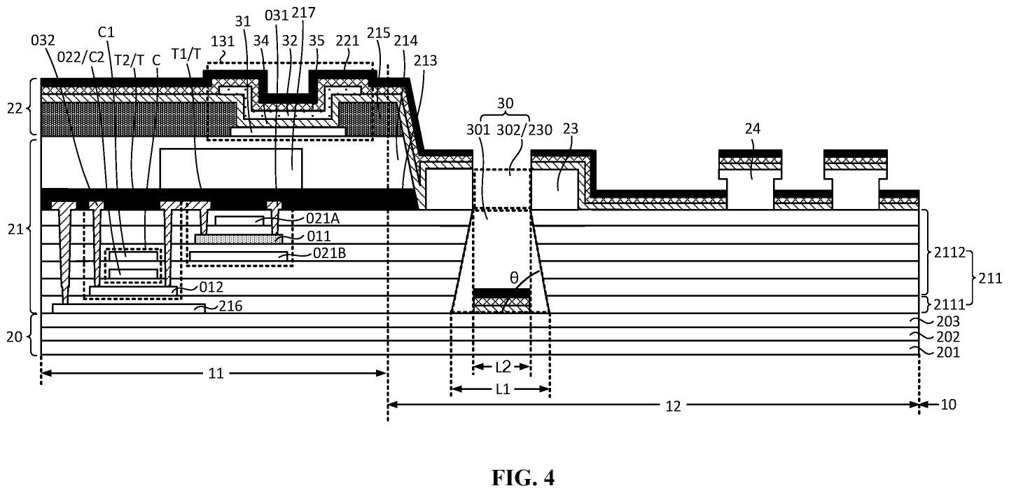

FIG. 4 is a sectional diagram of another display panel according to an embodiment of the present disclosure. As shown in FIG. 4, the array layer 21 further includes a metal isolation column 24, the metal isolation column 24 is located in the isolation region 12, and along the thickness direction of the base substrate 20, the metal isolation column 24 is located on the side of the first insulating layer 211 facing away from the base substrate 20. The material of the barrier layer 23 is metal, and the barrier layer 23 and the metal isolation column 24 is located in the same film layer.

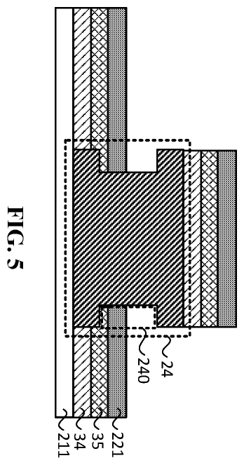

Specifically, FIG. 5 is a structural diagram of a metal isolation column according to an embodiment of the present disclosure. As shown in FIG. 4 and FIG. 5, the metal isolation column 24 is further disposed in the isolation region 12 which is between the display region 11 and the hole-punch region 10. A side wall of the metal isolation column 24 has a recess 240. When the first functional layer 34, the second functional layer 35 and the cathode 221 are formed by evaporation on a side of the metal isolation column 24 facing away from the base substrate 20, the first functional layer 34, the second functional layer 35 and the cathode 221 can be disconnected at the position of the recess 240. In this manner, when water vapor and oxygen in the environment seep through the first functional layer 34 and the second functional layer 35 at the cutting section of the hole-punch region 10, the transmission path will be cut off at the side wall of the metal isolation column 24, so the water vapor and oxygen cannot enter the display region 11, impact on the display quality of the display region 11 caused by the water vapor and oxygen can be reduced, and thus the display effect is improved.

The metal isolation column 24 is disposed around the hole-punch region 10 like the groove 30 to comprehensively separate the first functional layer 34, the second functional layer 35 and the cathode 221, so the impact of water vapor and oxygen on the display quality of the display region 11 is further reduced, and the display effect is improved.

It is to be noted that although the metal isolation column 24 can separate the cathode 221, due to the conductivity of a metal material of the metal isolation column 24, a conductive path can be formed between cathodes 221 on two sides of the metal isolation column 24 through the metal isolation column 24, so that the metal isolation column 24 cannot block the transmission of static electricity. In the embodiment of the present disclosure, the cathode 221 is separated by the groove 30, so that the preceding problem does not exist.

In the embodiment, the barrier layer 23 is disposed in the same layer as the metal isolation column 24 so that the setting of one film layer can be reduced, and thereby the purpose of reducing production costs and reducing the thickness of the display panel can be achieved.

Moreover, the material of the metal isolation column 24 is metal, and the barrier layer 23 may use the same material as the metal isolation column 24. Therefore, while the barrier layer plays a role in blocking etching, the barrier layer 23 and the metal isolation column 24 can be prepared in the same process, so that the process time can be shortened.

It is to be noted that the barrier layer 23 located in the same film layer as the metal isolation column 24 refers to that the barrier layer 23 and the metal isolation column 24 are formed through the same mask process, so that the number of masks can be reduced and manufacturing costs can be lowered.

In addition, FIG. 4 only shows the example where two metal isolation columns 24 are disposed in the isolation region 12. In other embodiments, one metal isolation column 24 or multiple metal isolation columns 24 may be disposed, which is not specifically limited in the embodiment of the present disclosure.

With continued reference to FIG. 3 and FIG. 4, optionally, the array layer 21 further includes a second transistor T2. The second transistor T2 includes a second active layer 012, and a material of the second active layer 012 is polycrystalline silicon. The first insulating layer 211 includes a first insulating sub-layer 2111 and a second insulating sub-layer 2112, and the second insulating sub-layer 2112 is located on a side of the first insulating sub-layer 2111 facing away from the base substrate 20. Along the thickness direction of the base substrate 20, the second active layer 012 is located between the first insulating sub-layer 2111 and the second insulating sub-layer 2112. Along the thickness direction of the base substrate 20, the bottom surface of the groove 30 is located on a side of the second insulating sub-layer 2112 adjacent to the base substrate 20.

Specifically, as shown in FIG. 3 and FIG. 4, the thin-film transistor T in the pixel driver circuit may include the second transistor T2. The second transistor T2 is a P-type low-temperature polycrystalline silicon (LTPS) thin-film transistor (P-type transistor). The LTPS transistor has the advantages of small size and good stability.

With continued reference to FIG. 3 and FIG. 4, exemplarily, the thin-film transistor T in the pixel driver circuit may include both the first transistor T1 and the second transistor T2. The first transistor T1 is an IGZO transistor, and the second transistor T2 is an LTPS transistor. The second transistor T2 includes a second active layer 012, a third gate layer 002 and a second source-drain electrode layer 032 which are laminated on a side of the base substrate 20.

The third gate layer 022 may be located on the second active layer 012. That is, the LTPS transistor is, but not limited to, a top gate structure.

With continued reference to FIG. 3 and FIG. 4, optionally, the pixel driver circuit further includes a storage capacitor C. The storage capacitor C includes a first electrode plate C1 and a second electrode plate C2, and the first electrode C1 is located on a side of the second electrode plate C2 facing away from the base substrate 20.

The second electrode plate C2 and the third gate layer 022 may share the same metal film layer structure. Therefore, the number of metal film layers can be reduced, and thus the purpose of reducing production costs and reducing the thickness of the display panel can be achieved.

Further, as shown in FIG. 3 and FIG. 4, the second gate layer 021B of the first transistor T1 and the first electrode plate C1 may be located in the same film layer, so the setting of one metal film layer can be reduced, and thereby the purpose of reducing production costs and reducing the thickness of the display panel can be achieved. Moreover, the second gate layer 021B of the first transistor T1 and the first electrode plate C1 may use the same material so that the second gate layer 021B of the first transistor T1 and the first electrode plate C1 can be prepared in the same process, shortening the process time. The preparation process of the second gate layer 021B of the first transistor T1 and the first electrode plate C1 is not limited thereto.

In the embodiment, along the thickness direction of the base substrate 20, the bottom surface of the groove 30 is located on the side of the second insulating sub-layer 2112 close to the base substrate 20, that is, the bottom surface of the groove 30 is located on a side of the second active layer 012 of the second transistor T2 close to the base substrate 20, so the groove 30 has sufficient depth to ensure that the cathode 221 can be disconnected at the position of the side wall of the groove 30. Therefore, when static electricity is introduced through the cathode 221 at the cutting section of the hole-punch region 10, the transmission path will be cut off at the side wall of the groove 30, and thus interference on the display region 11 caused by the static electricity is avoided. Moreover, a power signal transmitted on the cathode 221 cannot be transmitted through the groove 30 to the cutting section of the hole-punch region 10, so the problem of electrochemically corroded dark spots formed at the cutting section of the hole-punch region 10 is solved, and the display quality is improved.

Further, the depth of groove 30 may range from 500 nm to 1500 nm, ensuring that the groove 30 has sufficient depth to allow cathode 221 to be disconnected at the position of the side wall of the groove 30 while the difficulty of the process is reduced. Thus, the process is easy to achieve. The depth of the groove 30 is not limited thereto and is not limited in the embodiment of the present disclosure.

With continued reference to FIG. 2 to FIG. 4, optionally, along the thickness direction of the base substrate 20, the bottom surface of the groove 30 is located on a side of the base substrate 20 adjacent to the light-emitting functional layer 22.

As shown in FIG. 2 to FIG. 4, the bottom surface of the groove 30 is located on the side of the base substrate 20 close to the light-emitting functional layer 22, that is, the bottom surface of the groove 30 is located on the base substrate 20, so the impact on the encapsulation effect of the base substrate 20 caused by the damage to the film layer structure of the base substrate 20 when the groove 30 is provided through etching can be avoided.

It is to be noted that FIG. 2 to FIG. 4 illustrate the example where the bottom surface of the groove 30 is located on the surface position of the base substrate 20 close to the light-emitting functional layer 22. In this case, the damage to the film layer structure of the base substrate 20 is avoided, and the depth of the groove 30 may be increased as much as possible to ensure that the cathode 221 is disconnected at the sidewall of the groove 30. The position of the bottom surface of the groove 30 is not limited thereto.

In other embodiment, the position of the bottom surface of the groove 30 may be set according to actual requirements, which is not specifically limited in the embodiment of the present disclosure.

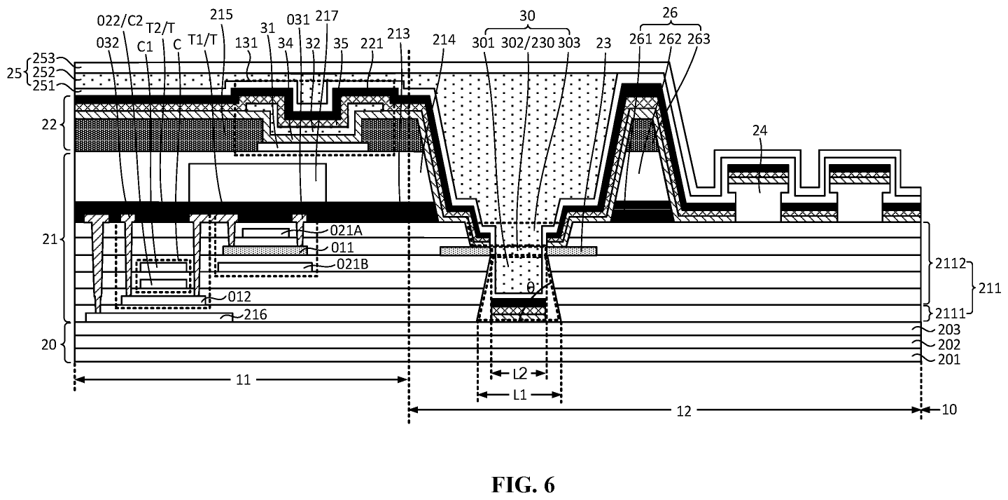

FIG. 6 is a sectional diagram of another display panel according to an embodiment of the present disclosure. As shown in FIG. 6, optionally, the display panel provided in the embodiment of the present disclosure further includes a thin-film encapsulation layer 25. The thin-film encapsulation layer 25 is located on a side of the light-emitting functional layer 22 facing away from the base substrate 20. The array layer 21 further includes an organic bank 26, where the organic bank 26 is located in the isolation region 12. Along the direction pointing from the display region 11 to the hole-punch region 10, the groove 30 is located on a side of the organic bank 26 adjacent to the display region 11.

Specifically, as shown in FIG. 6, the thin-film encapsulation layer 25 is disposed on the side of the light-emitting functional layer 22 facing away from the base substrate 20. The thin-film encapsulation layer 25 may include a first inorganic encapsulation layer 251, an organic encapsulation layer 252 and a second inorganic encapsulation layer 253 which are laminated. The first inorganic encapsulation layer 251 and the second inorganic encapsulation layer 253 can block water vapor and oxygen in the external environment, and the organic encapsulation layer 252 can provide a thin-film deposition condition of planarization for the subsequently formed inorganic encapsulation layer, relieve stress and cover surface steps and impurities to provide an excellent particle encapsulation effect. However, the water and oxygen barrier property of the organic encapsulation layer 252 is relatively poor.

Further, with continued reference to FIG. 6, the organic bank 26 is further disposed in the isolation region 12 between the display region 11 and the hole-punch region 10. The organic bank 26 is configured to block the organic encapsulation layer 252 in the thin-film encapsulation layer 25, preventing the organic encapsulation layer 252 from overflowing to the hole-punch region 10, and thereby preventing lateral corrosion of the display panel by water and oxygen in the external environment through the organic encapsulation layer 252.

Optionally, the organic bank 26 is disposed around the hole-punch region 10 like the groove 30 to comprehensively separate the organic encapsulation layer 252 in the thin-film encapsulation layer 25, thereby preventing the organic encapsulation layer 252 from overflowing to the hole-punch region 10 and avoiding lateral corrosion of the display panel by water and oxygen in the external environment through the organic encapsulation layer 252.

The organic bank 26 may include multiple organic film layers so that the organic bank 26 has sufficient height to prevent the overflow of the organic encapsulation layer 252. For example, as shown in FIG. 6, the organic bank 26 may include a first organic layer 261, a second organic layer 262 and a third organic layer 263 which are laminated.

Further, as shown in FIG. 4 and FIG. 6, the array layer 21 further includes a planarization layer 213, a third insulating layer 214 and a pixel defining layer 215. The planarization layer 213 is located on the side of the first insulating layer 211 facing away from the base substrate 20, the third insulating layer 214 is located on a side of the planarization layer 213 facing away from the base substrate 20, and the pixel defining layer 215 is located on a side of the third insulating layer 214 facing away from the base substrate 20. The pixel defining layer 215 includes a pixel opening. The light-emitting layer 32 is connected to the anode 31 through the pixel opening.

The first organic layer 261 may be located in the same film layer as the planarization layer 213 so that the first organic layer 261 and the planarization layer 213 can be prepared in the same process, and thus the process time is shortened.

Similarly, the second organic layer 262 may be located in the same film layer as the third insulating layer 214 so that the second organic layer 262 and the third insulating layer 214 can be prepared in the same process, and thus the process time is shortened.

The third organic layer 263 may be located in the same film layer as the pixel defining layer 215 so that the third organic layer 263 and the pixel defining layer 215 can be prepared in the same process, and thus the process time is shortened.

It is to be noted that in the embodiment of the present disclosure, being located in the same film layer refers to being formed through the same mask process. In this manner, the number of masks can be reduced, and manufacturing costs can be lowered.

With continued reference to FIG. 6, along the direction pointing from the display region 11 to the hole-punch region 10, the groove 30 is located on the side of the organic bank 26 close to the display region 11. In this manner, the groove 30 can accommodate a large amount of organic encapsulation layer 252, facilitating the organic bank 26 separating the organic encapsulation layer 252 in the thin-film encapsulation layer 25, ensuring that the organic encapsulation layer 252 cannot overflow to the hole-punch region 10, and thus preventing lateral corrosion of the display panel by water and oxygen in the external environment through the organic encapsulation layer 252.

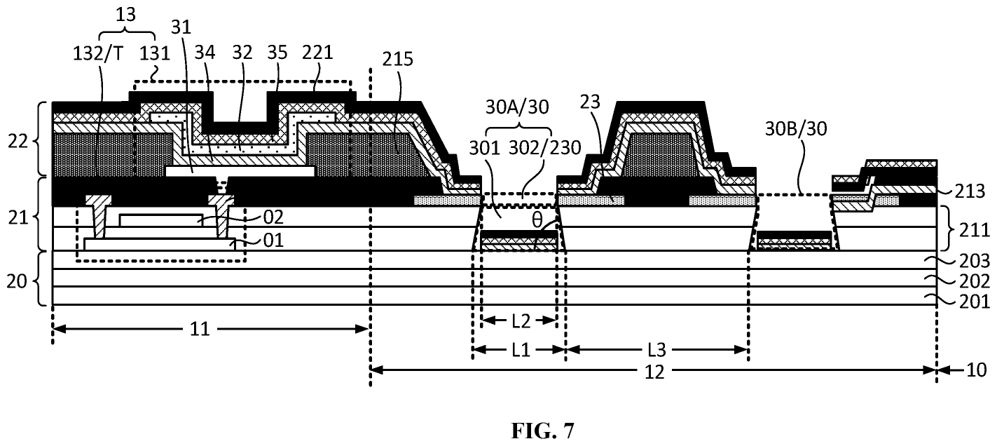

FIG. 7 is a sectional diagram of another display panel according to an embodiment of the present disclosure. As shown in FIG. 7, optionally, the at least one groove 30 includes a first groove 30A and a second groove 30B, and along the direction pointing from the display region 11 to the hole-punch region 10, the second groove 30B is located on a side of the first groove 30A facing away from the display region 11. Along the direction pointing from the display region 11 to the hole-punch region 10, a shortest distance L3 between the first groove 30A and the second groove 30B is greater than or equal to 2 μm.

To improve the separation effect of the cathode 221, at least two grooves 30 may be provided. Specifically, as shown in FIG. 7, an example where two grooves 30 are provided is illustrated. The two grooves 30 are the first groove 30A and the second groove 30B respectively. The cathode 221 is disconnected at both the first groove 30A and the second groove 30B so that a better separation effect can be achieved.

Further, along the direction pointing from the display region 11 to the hole-punch region 10, the shortest distance L3 between the first groove 30A and the second groove 30B is greater than or equal to 2 μm. In this manner, it can be ensured that the first groove 30A will not be communicated with the second groove 30B, moreover, the difficulty of the process can be reduced, and thus the process is easy to achieve.

It is to be noted that more grooves 30 may further be provided. The specific number of grooves 30 may be set according to the width of the isolation region 12, which is not specifically limited in the embodiment of the present disclosure.

If more grooves 30 are provided, along the direction pointing from the display region 11 to the hole-punch region 10, a shortest distance between adjacent grooves 30 may be greater than or equal to 2 μm so that the difficulty of the process can be reduced and the adjacent grooves 30 will not be communicated.

With continued reference to FIG. 3, FIG. 4 and FIG. 6, the array layer 21 further includes a light-shading metal layer 216. The light-shading metal layer 216 is located on a side of the first active layer 011 of the first transistor T1 close the base substrate 20. Along the thickness direction of the base substrate 20, a vertical projection of the light-shading metal layer 216 on the base substrate at least partially overlaps a vertical projection of the first active layer 011 on the base substrate. The light-shading metal layer 216 is configured to block a channel formed by the first active layer 011 to avoid external environmental light from illuminating the first active layer 011. Therefore, the first active layer 011 can be avoided from affecting an off-state current of the first transistor T1 due to exposure to light.

Further, along the thickness direction of the base substrate 20, the light-shading metal layer 216 may cover the first active layer 011 to avoid adverse impact of light on the first transistor T1. Whether the light-shading metal layer 216 covers the first active layer 011 is not limited.

On the basis of the same inventive concept, an embodiment of the present disclosure further provides a preparation method of a display panel for preparing any display panel provided in the preceding embodiments. Structures and explanations of terms which are the same as or correspond to the structures and explanations of terms of the preceding embodiments are not repeated here.

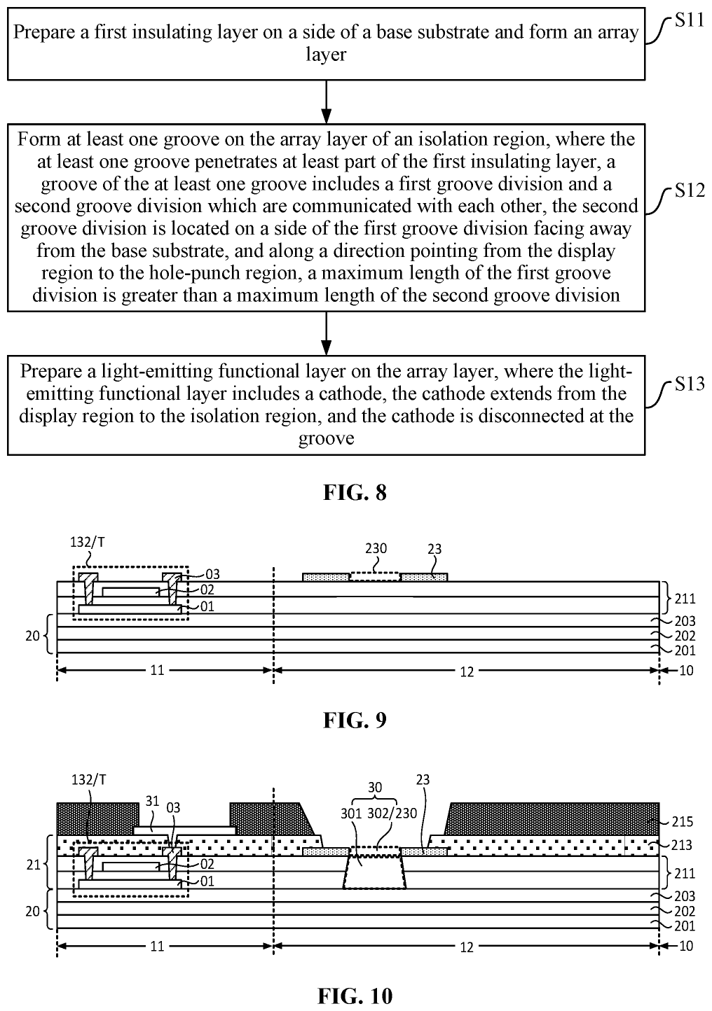

FIG. 8 is a flowchart of a preparation method of a display panel according to an embodiment of the present disclosure. As shown in FIG. 8, the preparation method includes steps described below.

In S11, a first insulating layer is prepared on a side of abase substrate and an array layer is formed.

Specifically, as shown in FIG. 2, the base substrate 20 may include a first base 201, a first inorganic layer 202 and a second base 203 which are sequentially disposed.

Materials of the first base 201 and the second base 203 may include, but are not limited to, organic materials such as polyimide.

The first inorganic layer 202 can block moisture and oxygen from entering the pixel driver circuit 132, thereby ensuring the driving performance of the pixel driver circuit 132. A material of the first inorganic layer 202 may include, but is not limited to, SiOx or SiNx.

Further, the first insulating layer 211 is prepared on a side of the base substrate 20, and the array layer 21 is formed. The array layer 21 includes the pixel driver circuit 132. The pixel driver circuit 132 includes at least one thin-film transistor T, and the thin-film transistor T may include an active layer 01, a gate layer 02 and a source-drain electrode layer 03 which are laminated.

The first insulating layer 211 may include multiple insulating film layers. The first insulating layer 211 is configured to isolate the active layer 01, the gate layer 02 and the source-drain electrode layer 03 to ensure the normal operation of the thin-film transistor T.

A material of the first insulating layer 211 may include, but is not limited to, SiOx or SiNx.

In S12, at least one groove is formed on the array layer of an isolation region, where the at least one groove penetrates at least part of the first insulating layer, a groove of the at least one groove includes a first groove division and a second groove division which are communicated with each other, the second groove division is located on a side of the first groove division facing away from the base substrate, and along a direction pointing from the display region to the hole-punch region, a maximum length of the first groove division is greater than a maximum length of the second groove division.

Specifically, as shown in FIG. 1 and FIG. 2, the display panel includes the hole-punch region 10, the display region 11 surrounding the hole-punch region 10 and the isolation region 12 located between the display region 11 and the hole-punch region 10.

The hole-punch region 10 is configured for placing a photosensitive element. The photosensitive element may be, but is not limited to, a camera, a light sensor, a distance sensor, a depth sensor, an iris recognition sensor or an infrared sensor.

With continued reference to FIG. 2, at least one groove 30 is formed in the isolation region 12, and the at least one groove 30 penetrates at least part of the first insulating layer 211. A groove 30 of the at least one groove 30 includes the first groove division 301 and the second groove division 302 which is located on the side of the first groove division 301 facing away from the base substrate 20, and the first groove division 301 and the second groove division 302 are communicated. Along the direction pointing from the display region 11 to the hole-punch region 10, the maximum length L1 of the first groove division 301 is greater than the maximum length L2 of the second groove division 302 so that the size of the first groove division 301 at the lower part of the groove 30 is greater than the size of the second groove division 302 at the upper part of the groove 30.

In S13, a light-emitting functional layer is prepared on the array layer, where the light-emitting functional layer includes a cathode, the cathode extends from the display region to the isolation region, and the cathode is disconnected at the groove.

Specifically, as shown in FIG. 1 and FIG. 2, the light-emitting functional layer 22 is prepared on the side of the array layer 21 facing away from the base substrate 20. The light-emitting functional layer 22 includes a light-emitting unit 131, and the light-emitting unit 131 may include the anode 31, the light-emitting layer 32 and the cathode 221 which are laminated. The light-emitting layer 32 may be an organic light-emitting layer (EML). Electrons are injected into the light-emitting layer 32 through the cathode 221, holes are injected into the light-emitting layer 32 through the anode 31, and electrons and holes are combined in the light-emitting layer 32 to emit light.

The cathode 221 is generally set as a whole layer, and therefore, the cathode 221 extends from the display region 11 to the cutting section of the hole-punch region 10. Along the direction pointing from the display region 11 to the hole-punch region 10, since the maximum length L1 of the first groove division 301 is greater than the maximum length L2 of the second groove division 302, when the cathode 221 is prepared, the side wall of the groove 30 is not easy to be covered by the cathode 221 so that the cathode 221 is disconnected at the side wall of the groove 30. Therefore, when static electricity is introduced through the cathode 221 at the cutting section of the hole-punch region 10, the transmission path will be cut off at the side wall of the groove 30 of the isolation region 12 so that the static electricity cannot enter the display region 11, electrical interference on subpixels 13 of the display region 11 caused by the static electricity can be avoided, and thus the problem of abnormal display of the display region 11 around the hole-punch region 10 is solved. Moreover, a power signal transmitted on the cathode 221 cannot be transmitted through the isolation region 12 to the cutting section of the hole-punch region 10 so that the problem of electrochemically corroded dark spots formed at the cutting section of the hole-punch region 10 is solved, and the display quality is improved.

Optionally, after the first insulating layer is prepared on the side of the base substrate, the step described below is further included.

A barrier layer is formed on a side of the first insulating layer facing away from the base substrate, where the barrier layer includes a hollowed-out region.

The step in which the at least one groove is formed on the array layer of the isolation region includes the step described below.

The first insulating layer is etched through the hollowed-out region so that the first groove division and the second groove division are formed, where the first groove division and the second groove division are communicated to form the groove.

Specifically, FIG. 9 and FIG. 10 are structural diagrams of a flow of a preparation method of a display panel according to an embodiment of the present disclosure. As shown in FIG. 9 and FIG. 10, after the first insulating layer 211 is prepared, the barrier layer 23 is prepared on the first insulating layer 211, and the hollowed-out region 230 is provided on the barrier layer 23.

In the subsequent preparation of the groove 30, the first insulating layer 211 is etched through the hollowed-out region 230 of the barrier layer 23 so that the second groove division 302 is formed in the hollowed-out region 230 and the first groove division 301 is formed in the first insulating layer 211. The barrier layer 23 can play a role in blocking the etching, and the etching of the first insulating layer 211 is implemented simultaneously along the vertical direction and the horizontal direction, forming the first groove division 301. Thus, the width of the first groove division 301 can be externally expanded. Finally, along the direction pointing from the display region 11 to the hole-punch region 10, the maximum length of the first groove division 301 is greater than the maximum length of the second groove division 302. In this manner, the steepness of the slope of the side wall of the groove 30 can be increased. As shown in FIG. 2, when the cathode 221 is formed on the side the first insulating layer 211 facing away from the base substrate 20, it is ensured that the cathode 221 is disconnected at the position of the side wall of the groove 30. Therefore, when static electricity is introduced through the cathode 221 at the cutting section of the hole-punch region 10, the transmission path will be cut off at the side wall of the groove 301, so that the static electricity cannot enter the display region 11, and thus interference on the display region 11 caused by the static electricity can be avoided. Moreover, a power signal transmitted on the cathode 221 cannot be transmitted through the groove 30 to the cutting section of the hole-punch region 10, so the problem of electrochemically corroded dark spots formed at the cutting section of the hole-punch region 10 is solved, and the display quality is improved.

Optionally, after the first insulating layer is prepared on the side of the base substrate, the step described below is further included.

A first active layer is formed on the side of the first insulating layer facing away from the base substrate, where a material of the first active layer is a metal oxide.

The barrier layer and the first active layer are formed through the same mask.

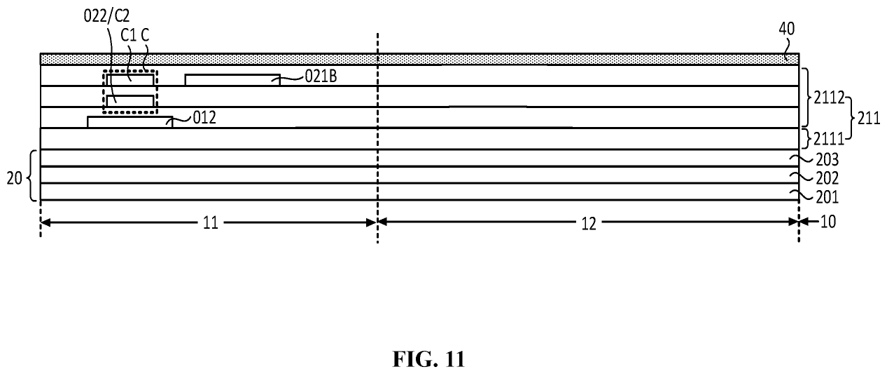

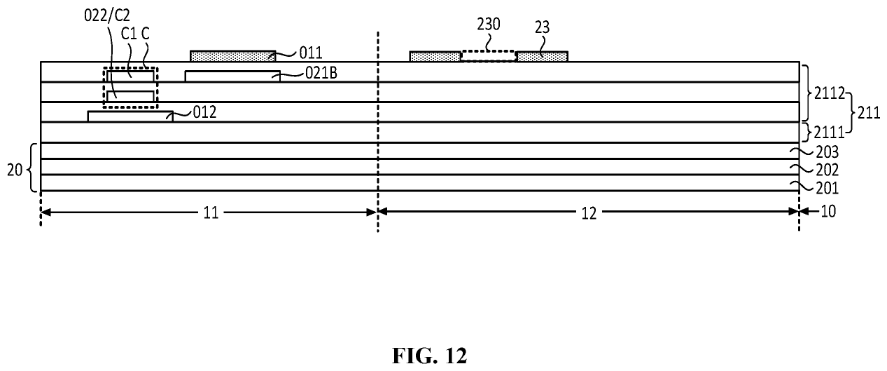

Specifically, FIG. 11 to FIG. 16 are structural diagrams of a flow of another preparation method of a display panel according to an embodiment of the present disclosure. As shown in FIG. 11 and FIG. 12, after the first insulating layer 211 is prepared on the side of the base substrate 20, a metal oxide layer 40 is prepared on the first insulating layer 211, and then the barrier layer 23 and the first active layer 011 are simultaneously formed through the same mask process. In this manner, the number of masks can be reduced, manufacturing costs can be reduced, and the process time can be shortened.

Optionally, after the barrier layer is formed on the side of the first insulating layer facing away from the base substrate, the step described below is further included.

A second insulating layer is formed on a side of the barrier layer facing away from the base substrate.

Before the first insulating layer is etched through the hollowed-out region, the step described below is further included.

The second insulating layer is etched so that a third groove division is formed, where a vertical projection of a side wall of the third groove division on the base substrate is located within a vertical projection of the barrier layer on the base substrate.

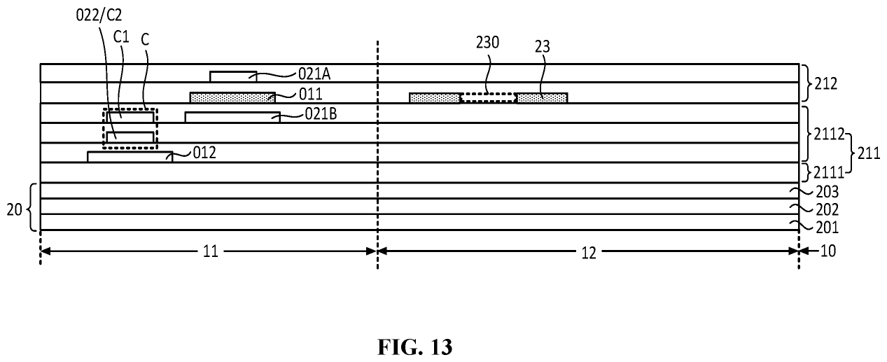

Specifically, as shown in FIG. 13, the second insulating layer 212 is formed on the barrier layer 23. The second insulating layer 212 may include one or more insulating film layers. A material of the second insulating layer 212 may include, but is not limited to, SiOx or SiNx to provide the insulation effect.

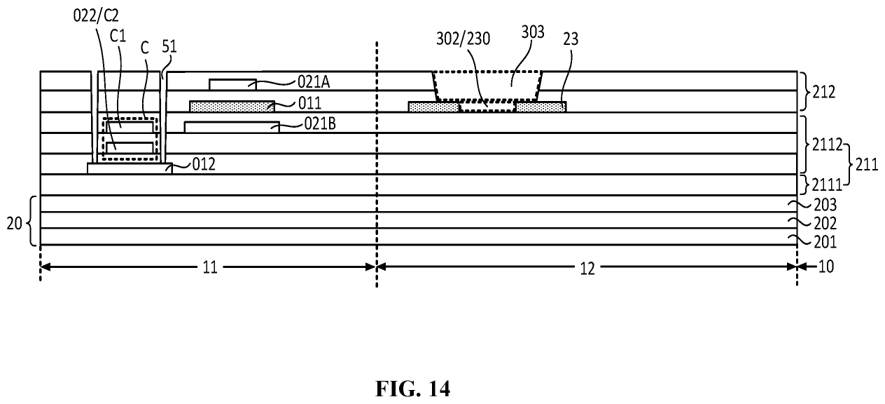

As shown in FIG. 14, the second insulating layer 212 is etched so that the third groove division 303 is formed on the second insulating layer 212. Moreover, the third groove division 303 exposes the hollowed-out region 230 in the barrier layer 23, and the hollowed-out region 230 forms the second groove division 302.

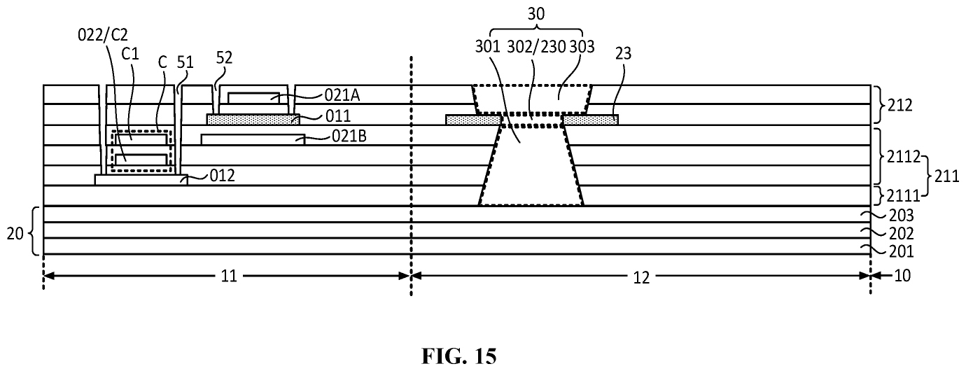

As shown in FIG. 14 and FIG. 15, along the thickness direction of the base substrate 20, a vertical projection of the side wall of the third groove division 303 overlaps a vertical projection of the barrier layer 23. In this manner, on the one hand, it can be ensured that the third groove division 303 can fully expose the hollowed-out region 230 in the barrier layer 23, thereby facilitating the subsequent etching of the first insulating layer 211 through the hollowed-out region 230 to form the first groove division 301; on the other hand, when the first insulating layer 211 is etched through the third groove division 303 and the hollowed-out region 230, the barrier layer 23 can completely block the etching, avoiding the etching of part of the first insulating layer 211 outside the hollowed-out region 230 that is not covered by the barrier layer 23.

Optionally, when the third groove division 303 is prepared, the second insulating layer 212 may be etched by using a dry etching process. Dry etching may be a technique that uses plasma for thin film etching.

In the embodiment, when the second insulating layer 212 is etched by using the dry etching process, a suitable gas may be selected according to the material of the second insulating layer 212 for fast reaction with the material of the second insulating layer 212, so that the purpose of etching removal can be achieved. Dry etching has the advantages of controllability, flexibility, good repeatability, safe operation, easy automation, no chemical waste liquid, no pollution introduced in the treatment process and high cleanliness.

Fluorine-based plasma (such as etching gas SF6 or CF4) may be used for etching the second insulating layer 212, ensuring that the etching effect is only achieved on the inorganic layer (that is, the second insulating layer 212), and no etching effect is achieved on the metal film layer, thereby avoiding damage to other metal structures.

Optionally, the step in which the first insulating layer is prepared on the side of the base substrate includes steps described below.

A first insulating sub-layer is formed on a side of the base substrate.

A second active layer is formed on a side of the first insulating sub-layer facing away from the base substrate, where a material of the second active layer is polycrystalline silicon.

A second insulating sub-layer is formed on a side of the second active layer facing away from the base substrate, where the first insulating sub-layer and the second insulating sub-layer form the first insulating layer.

After the second insulating layer is formed on the side of the barrier layer facing away from the base substrate, the method further includes steps described below.

A first connecting through hole is formed in the second insulating sub-layer and the second insulating layer.

A second connecting through hole is formed in the second insulating layer.

A first source-drain electrode layer and a second source-drain electrode layer are formed on a side of the second insulating layer facing away from the base substrate, where the first source-drain electrode layer and the first active layer are electrically connected through the second connecting through hole, and the second source-drain electrode layer and the second active layer are electrically connected through the first connecting through hole.

The third groove division and the first connecting through hole are formed through the same mask, and the first groove division and the second connecting through hole are formed through the same mask.

Specifically, as shown in FIG. 11, the first insulating sub-layer 2111, the second active layer 012 and the second insulating sub-layer 2112 are sequentially prepared on a side of the base substrate 20. The first insulating sub-layer 2111 and the second insulating sub-layer 2112 form the first insulating layer 211.

As shown in FIG. 14, after the second insulating layer 212 is prepared, the second insulating sub-layer 2112 and the second insulating layer 212 are etched so that the first connecting through hole 51 is formed in the second insulating sub-layer 2112 and the second insulating layer 212, and simultaneously, through the same mask process, the third groove division 303 and the second groove division 302 are formed. In this manner, the number of masks can be reduced, manufacturing costs can be reduced, and the process time can be shortened.

Then, as shown in FIG. 15, a second time of etching is performed on the second insulating layer 212 so that the second connecting through hole 52 is formed in the second insulating layer 212, and simultaneously, through the same mask process, the first groove division 301 is formed in the first insulating layer 211. In this manner, the number of masks can be reduced, manufacturing costs can be reduced, and the process time can be shortened.

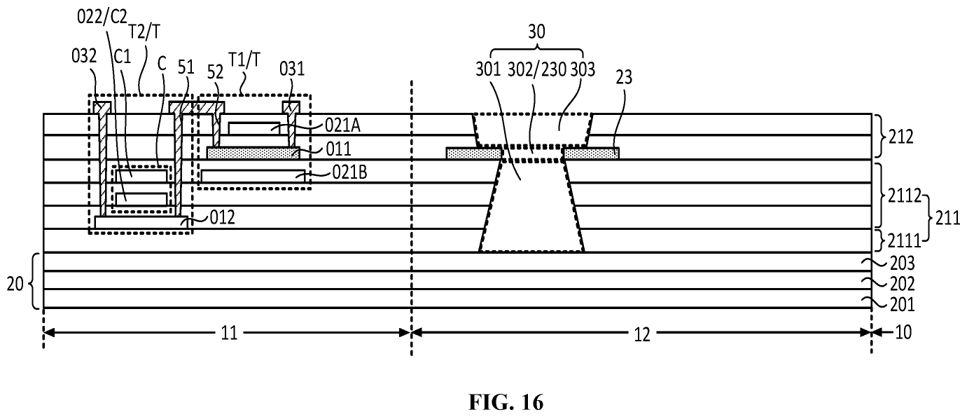

Further, as shown in FIG. 16, the first source-drain electrode layer 031 and the second source-drain electrode layer 032 are prepared on the second insulating layer 212. The first source-drain electrode layer 031 and the first active layer 011 are electrically connected through the second connecting through hole 52, and the second source-drain electrode layer 032 and the second active layer 012 are electrically connected through the first connecting through hole 51.

Optionally, after the first insulating layer is prepared on the side of the base substrate, the step described below is further included.

A metal isolation column is prepared on the side of the first insulating layer facing away from the base substrate, where the metal isolation column is located in the isolation region.

The barrier layer and the metal isolation column are formed through the same mask.

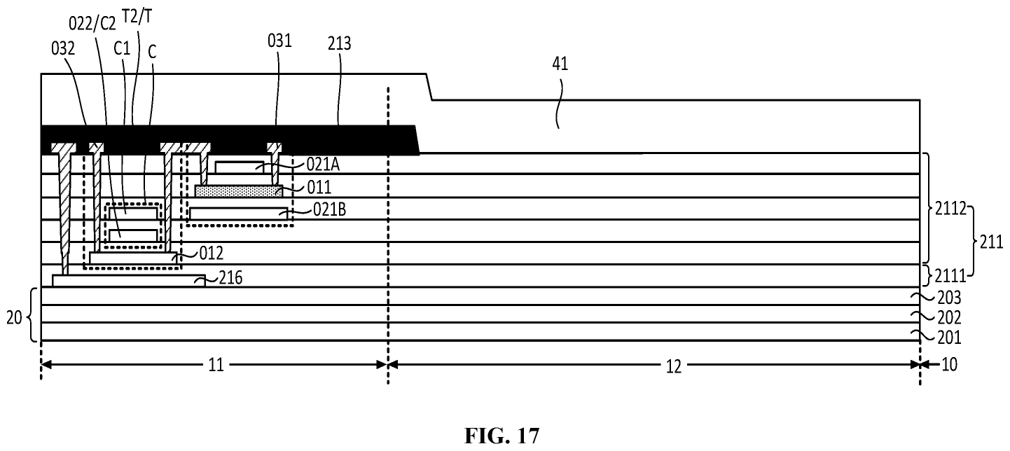

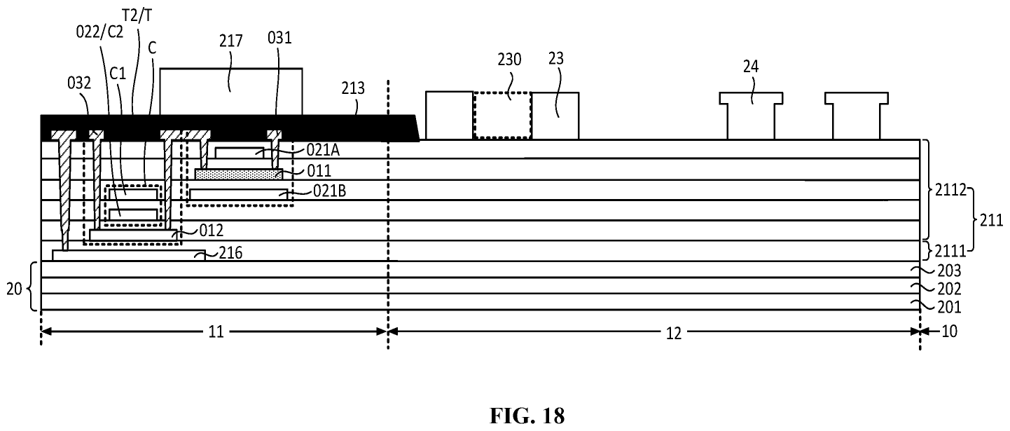

FIG. 17 to FIG. 19 are structural diagrams of a flow of another preparation method of a display panel according to an embodiment of the present disclosure. As shown in FIG. 17, after the first insulating layer 211 is prepared on the side of the base substrate 20, a metal material layer 41 is prepared on the side of the first insulating layer 211 facing away from the base substrate 20, and then, as shown in FIG. 18, the barrier layer 23 and the metal isolation column 24 are simultaneously formed through the same mask process. In this manner, the number of masks can be reduced, manufacturing costs can be reduced, and the process time can be shortened.

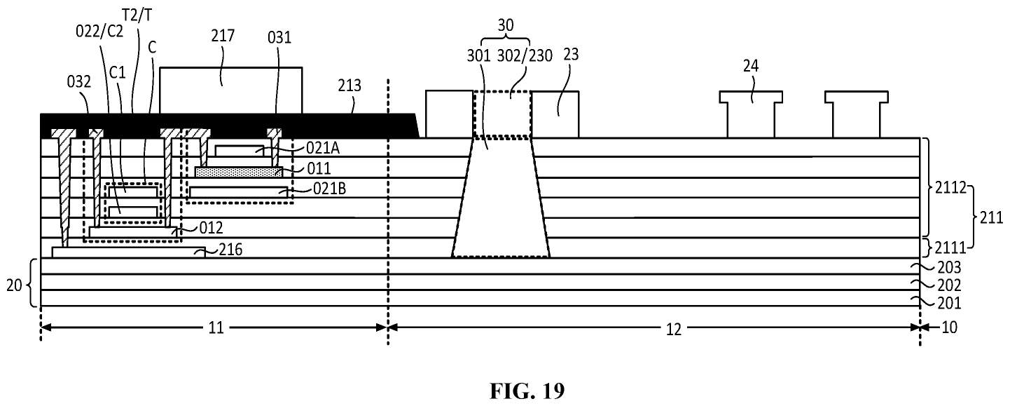

Further, as shown in FIG. 19, only one time of etching needs to be performed on the first insulating layer 211 through the hollowed-out region 230 in the barrier layer 23, then the first groove division 301 is formed in the first insulating layer 211, and thus the groove 30 can be formed.

When the groove 30 is formed, the first insulating layer 211 may be etched by using a dry etching process.

In the embodiment, dry etching may be a technique that uses plasma for thin film etching. When the first insulating layer 211 is etched by using the dry etching process, a suitable gas may be selected according to the material of the first insulating layer 211 for fast reaction with the material of the first insulating layer 211, so that the purpose of etching removal can be achieved. Dry etching has the advantages of controllability, flexibility, good repeatability, safe operation, easy automation, no chemical waste liquid, no pollution introduced in the treatment process and high cleanliness.

Optionally, fluorine-based plasma (such as etching gas SF6 or CF4) may be used for etching the first insulating layer 211, ensuring that the etching effect is only achieved on the inorganic layer (that is, the first insulating layer 211), and no etching effect is achieved on the metal film layer, thereby avoiding damage to other metal structures.

Further, as shown in FIG. 4 and FIG. 6, the array layer 21 further includes a first signal line 217. The first signal line 217 is located on the side of the planarization layer 213 facing away from the base substrate 20. The first signal line 217 may be, but is not limited to, a data signal line.

With continued reference to FIG. 17 to FIG. 19, optionally, the first signal line 217 and the metal isolation column 24 is formed through the same mask process, that is, the first signal line 217 and the metal isolation column 24 are located in the same film layer. In this manner, the setting of one film layer can be reduced, and thereby the purpose of reducing production costs and reducing the thickness of the display panel can be achieved. Moreover, the number of masks can further be reduced, manufacturing costs can be reduced, and the process time can be shortened.

It is to be noted that as shown in FIG. 17 to FIG. 19, a metal isolation column 24 may include three metal layers. The three metal layers are a titanium layer, an aluminum layer and a titanium layer in sequence, that is, the metal isolation column 24 is a titanium/aluminum/titanium three-layer metal structure. When the metal isolation column 24 is prepared, the titanium/aluminum/titanium three-layer metal structure may be etched. Since the speed of etching titanium is much lower than the speed of etching aluminum, when the titanium/aluminum/titanium three-layer metal structure is etched, the aluminum layer in the middle will be etched first, so that side walls of the aluminum layer are etched first and thus recesses inward are formed, forming the structure shown in FIG. 5.

The shape of the side wall of the metal isolation column 24 in FIG. 4, FIG. 6, FIG. 18 and FIG. 19 is only a simplified illustration and is not a limitation on the present disclosure. The side wall formed by the actual etching process may not have a regular shape.

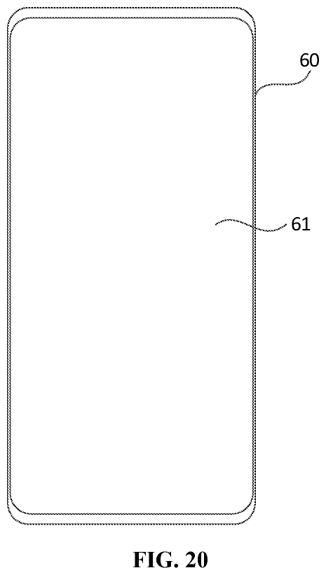

Based on the same inventive concept, an embodiment of the present disclosure further provides a display device. FIG. 20 is a structural diagram of a display device according to an embodiment of the present disclosure. As shown in FIG. 20, the display device 60 includes the display panel 61 according to any embodiment of the present disclosure. Therefore, the display device 60 according to the embodiment of the present disclosure has the technical effects of the technical solution in any one of the preceding embodiments, and structures and explanations of terms which are the same as or correspond to the structures and explanations of terms in the preceding embodiments are not repeated here.

The display device 60 provided in the embodiment of the present disclosure may be the cellphone shown in FIG. 20 or may be any other electronic product having a display function. The electronic product includes, but is not limited to, a television, a laptop, a desktop display, a tablet, a digital camera, a smart bracelet, smart glasses, an in-vehicle display, a medical device, an industrial control device or an interactive touch terminal. The display device 60 is not specially limited in the embodiment of the present disclosure.

It is to be understood that various forms of processes shown above may be adopted with steps reordered, added or deleted. For example, the steps described in the present disclosure may be performed in parallel, sequentially or in different sequences, as long as the desired results of the technical solutions of the present disclosure can be achieved, and no limitation is imposed herein.

The preceding embodiments do not limit the scope of the present disclosure. It is to be understood by those skilled in the art that various modifications, combinations, sub-combinations and substitutions may be performed according to design requirements and other factors. Any modification, equivalent substitution, improvement or the like made within the spirit and principle of the present disclosure is within the scope of the present disclosure.

What is claimed is:

1. A display panel, comprising a hole-punch region, a display region surrounding the hole-punch region and an isolation region located between the display region and the hole-punch region;
wherein the display panel further comprises a base substrate, an array layer and a light-emitting functional layer, the array layer and the light-emitting functional layer are sequentially located on a side of the base substrate, wherein
the array layer further comprises a first insulating layer;
the light-emitting functional layer comprises a cathode, and the cathode extends from the display region to the isolation region; and
a groove is provided in the isolation region, and the groove penetrates at least part of the first insulating layer;
the groove comprises a first groove division and a second groove division which are communicated with each other, and the second groove division is located on a side of the first groove division facing away from the base substrate; and
along a direction pointing from the display region to the hole-punch region, a maximum length of the first groove division is greater than a maximum length of the second groove division, and the cathode is disconnected at the groove.

2. The display panel according to claim 1, wherein
an angle between a bottom surface of the first groove division and a side wall of the first groove division is θ, wherein 0<θ<90°.

3. The display panel according to claim 1, wherein
the display panel further comprises a barrier layer, and the barrier layer is located on a side of the first insulating layer facing away from the base substrate; and
the second groove division penetrates the barrier layer, and a vertical projection of the second groove division on the base substrate is located within a vertical projection of the first groove division on the base substrate.

4. The display panel according to claim 3, wherein
a material of the barrier layer comprises a metal oxide or metal.

5. The display panel according to claim 3, wherein
the array layer further comprises a first transistor, the first transistor comprises a first active layer, and a material of the first active layer is a metal oxide; and
a material of the barrier layer is a metal oxide, and the barrier layer and the first active layer are located in a same film layer.

6. The display panel according to claim 5, wherein
the array layer further comprises a second insulating layer, and along a thickness direction of the base substrate, the second insulating layer is located between the barrier layer and the light-emitting functional layer;
the groove further comprises a third groove division communicated with the second groove division, and the third groove division is located on a side of the second groove division facing away from the base substrate; and
the third groove division penetrates the second insulating layer, and a vertical projection of the third groove division on the base substrate covers the vertical projection of the second groove division on the base substrate.

7. The display panel according to claim 6, wherein
a vertical projection of a side wall of the third groove division on the base substrate is located within a vertical projection of the barrier layer on the base substrate.

8. The display panel according to claim 6, wherein
along the direction pointing from the display region to the hole-punch region, a shortest distance between a side wall of the third groove division and a side wall of the second groove division is d1, wherein d1≥10 μm.

9. The display panel according to claim 3, wherein
the array layer further comprises a metal isolation column, the metal isolation column is located in the isolation region, and along a thickness direction of the base substrate, the metal isolation column is located on the side of the first insulating layer facing away from the base substrate; and
a material of the barrier layer is metal, and the barrier layer and the metal isolation column are located in a same film layer.

10. The display panel according to claim 1, wherein
the array layer further comprises a second transistor, the second transistor comprises a second active layer, and a material of the second active layer is polycrystalline silicon;
the first insulating layer comprises a first insulating sub-layer and a second insulating sub-layer, and the second insulating sub-layer is located on a side of the first insulating sub-layer facing away from the base substrate;
along a thickness direction of the base substrate, the second active layer is located between the first insulating sub-layer and the second insulating sub-layer; and
along the thickness direction of the base substrate, a bottom surface of the groove is located on a side of the second insulating sub-layer adjacent to the base substrate.

11. The display panel according to claim 10, wherein
along the thickness direction of the base substrate, the bottom surface of the groove is located on a side of the base substrate adjacent to the light-emitting functional layer.

12. The display panel according to claim 1, wherein
the display panel further comprises a thin-film encapsulation layer, and the thin-film encapsulation layer is located on a side of the light-emitting functional layer facing away from the base substrate;
the array layer further comprises an organic bank, and the organic bank is located in the isolation region; and
along the direction pointing from the display region to the hole-punch region, the groove is located on a side of the organic bank adjacent to the display region.

13. The display panel according to claim 1, wherein
the groove comprises a first groove and a second groove, and along the direction pointing from the display region to the hole-punch region, the second groove is located on a side of the first groove facing away from the display region; and
along the direction pointing from the display region to the hole-punch region, a shortest distance between the first groove and the second groove is greater than or equal to 2 μm.

14. A preparation method of a display panel, wherein the display panel comprises a hole-punch region, a display region surrounding the hole-punch region and an isolation region located between the display region and the hole-punch region; and
the preparation method comprises:
preparing a first insulating layer on a side of a base substrate and forming an array layer;
forming a groove on the array layer of the isolation region, wherein the groove penetrates at least part of the first insulating layer, the groove comprises a first groove division and a second groove division which are communicated with each other, the second groove division is located on a side of the first groove division facing away from the base substrate, and along a direction pointing from the display region to the hole-punch region, a maximum length of the first groove division is greater than a maximum length of the second groove division; and
preparing a light-emitting functional layer on the array layer, wherein the light-emitting functional layer comprises a cathode, the cathode extends from the display region to the isolation region, and the cathode is disconnected at the groove.

15. The preparation method according to claim 14,
after preparing the first insulating layer on the side of the base substrate, the method further comprising:
forming a barrier layer on a side of the first insulating layer facing away from the base substrate, wherein the barrier layer comprises a hollowed-out region;
wherein forming the groove on the array layer of the isolation region comprises:
etching the first insulating layer through the hollowed-out region to form the first groove division and the second groove division, wherein the first groove division and the second groove division are communicated to form the groove.

16. The preparation method according to claim 15,
after preparing the first insulating layer on the side of the base substrate, further comprising:
forming a first active layer on the side of the first insulating layer facing away from the base substrate, wherein a material of the first active layer is a metal oxide;
wherein the barrier layer and the first active layer are formed through a same mask.

17. The preparation method according to claim 16,
after forming the barrier layer on the side of the first insulating layer facing away from the base substrate, the method further comprising:
forming a second insulating layer on a side of the barrier layer facing away from the base substrate; and
before etching the first insulating layer through the hollowed-out region, the method further comprising:
etching the second insulating layer to form a third groove division, wherein a vertical projection of a side wall of the third groove division on the base substrate is located within a vertical projection of the barrier layer on the base substrate.

18. The preparation method according to claim 17, wherein
preparing the first insulating layer on the side of the base substrate comprises:
forming a first insulating sub-layer on a side of the base substrate;
forming a second active layer on a side of the first insulating sub-layer facing away from the base substrate, wherein a material of the second active layer is polycrystalline silicon; and
forming a second insulating sub-layer on a side of the second active layer facing away from the base substrate, wherein the first insulating sub-layer and the second insulating sub-layer form the first insulating layer; and
after forming the second insulating layer on the side of the barrier layer facing away from the base substrate, the method further comprises:
forming a first connecting through hole in the second insulating sub-layer and the second insulating layer;
forming a second connecting through hole in the second insulating layer; and
forming a first source-drain electrode layer and a second source-drain electrode layer on a side of the second insulating layer facing away from the base substrate, wherein the first source-drain electrode layer and the first active layer are electrically connected through the second connecting through hole, and the second source-drain electrode layer and the second active layer are electrically connected through the first connecting through hole;
the third groove division and the first connecting through hole are formed through a same mask, and the first groove division and the second connecting through hole are formed through a same mask.

19. The preparation method according to claim 15,
after preparing the first insulating layer on the side of the base substrate, the method further comprising:
preparing a metal isolation column on the side of the first insulating layer facing away from the base substrate, wherein the metal isolation column is located in the isolation region;
wherein the barrier layer and the metal isolation column are formed through a same mask.

20. A display device, comprising a display panel; wherein the display panel comprises a hole-punch region, a display region surrounding the hole-punch region and an isolation region located between the display region and the hole-punch region;
wherein the display panel further comprises a base substrate, an array layer and a light-emitting functional layer, the array layer and the light-emitting functional layer are sequentially located on a side of the base substrate, wherein
the array layer further comprises a first insulating layer;
the light-emitting functional layer comprises a cathode, and the cathode extends from the display region to the isolation region; and
a groove is provided in the isolation region, and the groove penetrates at least part of the first insulating layer;
the groove comprises a first groove division and a second groove division which are communicated with each other, and the second groove division is located on a side of the first groove division facing away from the base substrate; and
along a direction pointing from the display region to the hole-punch region, a maximum length of the first groove division is greater than a maximum length of the second groove division, and the cathode is disconnected at the groove.
